(19) United States
(12) Patent Application Publication
(10) Pub. No.: US 2026/0310071 A1
(43) Pub. Date: Oct. 8, 2026

(54) System and Process for Imprinting

(71) Applicant: Morphotonics Holding B.V., Veldhoven (NL)

(72) Inventors: Rob Antonius Waltherus Neelen, Veldhoven (NL); Jan Matthijs Ter Meulen, Veldhoven (NL)

(21) Appl. No.: 19/480,485

(22) PCT Filed: May 6, 2024
(86) PCT No.: PCT/NL2024/050231

§ 371 Date: Oct. 31, 2025

(30) Foreign Application Priority Data
May 8, 2023 (NL) 2034770

(51) Int. Cl. G03F 7/00; G03F 9/00

(52) U.S. Cl. CPC G03F 7/0002; G03F 9/7042

(57) ABSTRACT

The invention relates to a system and process for imprinting, in particular nanoimprinting. The system includes thereto a combination of a roller configured for rolling at least one flexible stamp over at least one substrate which is to be imprinted, a stage configured for providing support to at least one carrier and/or at least one substrate during imprinting and a carrier configured for carrying at least one substrate which is to be imprinted.

### CROSS-REFERENCE TO RELATED APPLICATIONS

This application is the United States national phase of International Patent Application No. PCT/NL2024/050231 filed May 6, 2024, and claims priority to The Netherlands Patent Application No. 2034770 filed May 8, 2023, the disclosures of which are hereby incorporated by reference in their entireties.

### BACKGROUND OF THE INVENTION

### Field of the Invention

The invention relates to a system for imprinting, in particular nanoimprinting. The invention also relates to a process for imprinting, in particular nanoimprinting.

### Description of Related Art

Imprinting, and in particular nanoimprinting, requires very accurate aligning between the stamp used for imprinting and the substrate which is to be imprinted. However, due to the relatively small structures, which can range for example from 500 micrometer down to 25 nanometer, the alignment requires a high level of accuracy. Typically, the substrate which is to be imprinted is aligned with respect to the stage upon which the substrate is positioned during the imprinting process. The stage can be provided with alignment markers and/or a receiving space wherein the substrate can be received and/or an abutment to help alignment of the substrate. The known systems have the drawback that the alignment step is rather time consuming and sensitive for aligning errors and damaging of the substrate.

### SUMMARY OF THE INVENTION

Hence, it is al goal of the invention to provide a system and process for imprinting, in particular nanoimprinting wherein the alignment required for the imprinting is improved.

The invention provides thereto a system for imprinting, in particular nanoimprinting, comprising:
at least one roller configured for exerting pressure onto at least one substantially flexible stamp and/or at least one substrate which is to be imprinted;
at least one carrier configured for carrying at least one substrate which is to be imprinted; and
at least one stage which is in particular configured for providing support to at least one carrier and/or at least one substrate during imprinting;
   wherein at least one roller and at least one stage are mutually displaceable in an imprint direction in particular such that imprinting is facilitated; and wherein at least one carrier and at least one stage are mutually displaceable between at least:
an adjusting configuration, wherein said carrier and said stage are mutually displaceable in at least one direction which differs from the imprint direction in particular such that at least one substrate can be aligned with respect to said stage and/or with respect to said carrier; and
an imprinting configuration, wherein at least one carrier is positioned (directly) upon and/or wherein at least one carrier engages at least one stage in particular such that at least one substrate provided upon said carrier and/or said stage can be imprinted.

The system according to the present invention in particular relates to a roll-to-plate imprinting process. The system according to the present invention has several benefits. In particular the combination of at least one carrier which is configured for carrying at least one substrate which is to be imprinted with at least one stage configured for providing support to at least one carrier and/or at least one substrate during imprinting, wherein said carrier and said stage are mutually displaceable enables that alignment of the substrate is facilitated in a relatively simple and effective manner. The system according to the invention enables a more efficient system in which the time required for the alignment can be reduced. Accurate alignment of the substrate with respect both the stage and the (flexible) stamp is very important in order to facilitate a decent imprinting process and/or to improve repeatability of resulting imprints. The combination of a stage and a carrier basically provides a two-layer surface which makes it possible to precisely align the substrate with respect to the stage and/or the flexible the stamp. The carrier further enables that direct engagement of the substrate can be prevented, in particular during loading of the substrate into the system, during alignment of the substrate within the system and/or during unloading of the imprinted substrate from the system. Typically, in prior art system, the substrate, and it particular the edges thereof need to be touched, for example via clamps, for the (un)loading and/or alignment steps. However, touching of the substrate, and even the non-active areas thereof, can negatively affect the quality of the final product. The system according to the present invention allows for loading, unloading and alignment of the substrate without having to touch the edges of the substrate. This prevents deformations and defects of the substrate due to handling.

At least one carrier is in particular configured for carrying at least one substrate which is to be imprinted and preferably has a function to provide a stable base for the substrate to lay on. At least one carrier typically comprises at least one support surface for carrying at least one substrate. At least part of the carrier, in particular at least part of the support surface, may be substantially flat. A further function of the carrier is enabling movement of the substrate in at least one direction for aligning purposes. The carrier further provides for easy loading of substrate(s) into the system and for moving substrate(s) with respect to the roller and/or the flexible stamp. The function of the carrier can also be described as enabling the adjustment of the position of the substrate in at least an y-direction and Rz direction. The direction of imprinting thereby equals the x-direction. In this way the carrier can align the substrate precisely in all directions without touching its edges.

At least one roller is in particular configured for exerting pressure onto at least one flexible stamp and/or at least one substrate which is to be imprinted. It is for example imaginable that at least one roller is configured for rolling at least one flexible stamp over at least one substrate which is to be imprinted. At least one roller is thereby configured for co-action with at least one flexible stamp which is configured for imprinting. The substantially flexible stamp can also be referred to as flexible substrate. Typically the substantially flexible stamp comprises a textured area. The textured can for example comprises a texture with dimension typically in the range from 500 micrometer down to 25 nanometer. The flexible stamp is in particular configured for nano-imprint lithography transfer processes. It is also imaginable that at least one flexible stamp is attached to at least one roller and/or that at least one flexible stamp is provided over at least one roller. The roller can for example be at least partially covered with at least one flexible stamp.

At least one stage is in particular configured for providing support to at least one carrier and/or at least one substrate during imprinting. The support provided by the stage can be direct and/or indirect support. Typically, the substrate will be supported by the stage during imprinting whilst the carrier is located between the substrate and the stage. At least part of the stage is preferably substantially flat. In particular part of the carrier upon which the substrate is to be positioned during imprinting is substantially flat. At least one stage is preferably substantially rigid. Rigidity of the stage is preferred to ensure stable support during the imprinting process. It can for example also be said that the stage is stable in shape.

At least one carrier and at least one stage can be positioned at a distance from each other in the adjusting configuration. At least one carrier and at least one stage are mutually displaceable between at least one adjusting configuration and at least one imprinting configuration. The adjusting configuration or adjusting configuration is in particular a dynamic position, wherein the carrier and the stage are mutually displaceable in at least one direction which differs from the imprint direction in particular such that at least one substrate provided upon said carrier can be aligned with respect to said stage. It is also conceivable that the carrier and the stage are mutually displaceable in the imprint direction and at least one further direction in the adjusting configuration. There can be several different configurations between the carrier and the stage in the adjusting configuration, depending on the desired alignment configuration. The imprinting configuration is in particular substantially a mutually static position or configuration in terms of mutual alignment wherein the carrier is positioned in particular directly upon the stage in particular such that a substrate provided upon the carrier can be imprinted. During imprinting the stage, including the carrier and substrate will be mutually displaced with respect to at least one roller.

At least one roller and at least one stage are in particular mutually displaceable in an imprint direction in particular such that imprinting is facilitated. Typically, at least one roller and at least one stage are also displaceable in distance with respect to each other. It is for example imaginable that at least one roller and/or at least one stage are displaceable in vertical direction. It is imaginable that the mutual distance between at least one roller and at least one stage is adjustable. It is also conceivable that the mutual distance between at least one roller and at least one carrier is adjustable and/or that the mutual distance between at least one carrier and at least one stage is adjustable. In this way, the imprinting process can be further optimized.

It is also possible that, in at least one adjusting configuration, at least one carrier and at least one stage are mutually displaceable in at least one direction, and preferably multiple directions, within a plane which is substantially parallel to a plane defined by said stage and/or said carrier, wherein at least one direction differs from the imprint direction. In this way, alignment of the carrier, and thus of the substrate provided thereon, with respect to the stage can be effectively achieved. The carrier and stage can for example be over at least 90 degrees adjustable within the defined plane, preferably over at least 180 degrees and more preferably over 360 degrees within the defined plane.

The system may comprise at least one primary actuator for adjusting the mutual position of at least one roller and at least one stage. Hence, at least one roller and at least one stage can be mutually displaceable by means of at least one primary actuator. The system, and in particular the actuator, may further comprise at least one drive unit. The primary actuator can be configured for adjusting the mutual distance between the stage and the roller and/or the mutual displacement in the imprint direction such that imprinting is facilitated.

The system may also comprise at least one secondary actuator for adjusting the mutual position of at least one carrier and at least one stage. The system may for example comprise at least one secondary actuator for adjusting the position of at least one carrier with respect to at least one stage. Adjusting the position of at least one carrier with respect to at least one stage via at least one secondary actuator is in particular possible at least in the adjusting configuration. The primary actuator and secondary actuator, if applied, are preferably independently controllable. At least one secondary actuator can also be configured for adjusting the position of at least one carrier with respect to at least one stage between the adjusting configuration and the imprinting configuration and/or for adjusting at least one carrier with respect to at least one stage into an aligned configuration in the adjusting configuration. It is also imaginable that at least one secondary actuator is configured for displacing at least one carrier with respect to at least one stage in at least one direction which differs from the imprint direction, in particular in the adjusting configuration.

At least one primary actuator and/or at least one secondary actuator could for example be a DC motor, stepper motor, servo motor, voice coil actuator or linear actuator. Depending on the selected actuator a transmission can be used to achieve the required resolution, such as a gear box, planetary gear box, spindle, rocker mechanism or eccentric wheel.

The system may also comprise at least one control unit for controlling the mutual displacement between at least one roller and at least one stage and/or between at least one carrier and at least one stage. At least one control unit can for example be configured to control the mutually displacement of at least one stage and at least one carrier between the adjusting configuration and the imprinting configuration. It is also conceivable that at least one control unit is configured to control alignment of the carrier with respect to the stage in the adjusting configuration.

In a preferred embodiment, at least part of at least one carrier is substantially situated between at least one roller and at least one stage at least in the imprinting configuration. It is also imaginable that at least part of at least one carrier is substantially situated between at least one roller and at least one stage in the imprinting configuration and the adjusting configuration. This is beneficial for the aligning process.

In a further preferred embodiment, at least part of at least one carrier substantially encloses at least part of at least one stage, in particular at least in the imprinting configuration. It is for example imaginable that at least one carrier substantially encloses at least part of at least one stage in line with the imprint direction. Possibly, at least part of at least one carrier substantially encloses at least part of at least one stage in both the imprinting configuration and the adjusting configuration. In a further preferred embodiment, at least one carrier comprises at least one belt, in particular an endless belt. The use of at least one belt has several benefits. The (endless) belt enables easy alignment of the carrier, and thus of the substrate which is to be imprinted, in the adjusting configuration. The belt further enables that the system according to the present invention allows for loading, unloading and alignment of the substrate without having to touch the edges of the substrate in an effective manner. The substrate(s) can be provided onto the belt in a simple manner, wherein further displacement of the substrate can be achieved via movement of the belt. At least one endless belt preferably encloses at least one stage. In a preferred embodiment, at least one endless belt encloses at least one stage such that the belt direction of the endless belt is substantially equal to or opposite of the imprint direction. Hence, the belt direction and imprint direction can both be in the x-direction. The belt direction should be interpreted as the travel direction of the belt. In case the system comprises a carrier comprising an endless belt, it is conceivable that said endless belt co-acts with at least two rollers, in particular guidance rollers. It is also imaginable that at least one roller is a driven roller. It is for example conceivable that the endless belt is attached around at least two rollers which are positioned at a distance from each other. It is also conceivable that at least one carrier comprises at least two guidance rollers and at least one endless belt which is positioned over said guidance rollers. The system may further comprise at least one housing, wherein at least part of the housing is connected or connectable to at least two guidance rollers. It is imaginable that the housing is connected or connectable to the at least one carrier, in particular the at least one endless belt, and/or to the at least one stage. This embodiment can provide a stable cooperation between the carrier and the stage. It is imaginable that the at least one carrier, in particular the at least one endless belt, and/or to the at least one stage are displaceably connected to the at least one housing, for example by making use of at least one spring and/or at least one piston. The system may comprises at least one further actuator for actuating the belt. It is conceivable that the housing is connected to at least two guidance rollers of the at least one endless belt via at least one actuator and preferably at least two actuators, wherein at least one actuator is preferably a voice coil actuator.

It is possible that at least one carrier and/or at least one substrate provided upon at least one carrier can be coupled to at least one stage via air regulation, for example via vacuum or partial vacuum. In a further preferred embodiment, at least part of at least one carrier is permeable to air. Such embodiment could further enhance the efficiency of the overall imprinting process and the accuracy of the alignment. It is for example imaginable that fixation of at least one substrate on the carrier is achieved via an air flow and/or that the carrier is displaced towards the stage via an air flow. It is also imaginable that fixation of at least one substrate on the carrier is achieved via a (partial) vacuum and/or that the carrier is displaced towards the stage via a (partial) vacuum. At least one carrier may for example comprise a plurality of air pockets, which can be configured to retain the substrate. In a further preferred embodiment, at least part of at least one carrier comprises a porous structure. At least part of the porous structure is preferably permeable to air. Preferably, at least part of least one carrier comprises a homogenous structure. In particular the area upon which the substrate is to be positioned should be substantially homogeneous. Differences in the structure and/or texture of the carrier could negatively affect the overall imprinting process, since the substrate will be positioned upon the carrier during imprinting. At least part of at least one carrier may also comprise a web structure and/or mesh structure. It I for example conceivable that at least part of at least one carrier comprises a mesh, a raster, a matrix, a perforated structure and/or a woven structure. Hence, at least part of at least one carrier may comprise an at least partially open structure. It is for example imaginable that at least one carrier comprises cut outs, grooves and/or through holes. Such air-permeable structure can be beneficial in order to enable vacuum fixation of at least one substrate on the carrier. It is preferred that at least one carrier is substantially uniform in optical characteristics and/or mechanical characteristics. Hence, at least one carrier is preferably uniform in structure, colour, transparency, density, thickness and/or flexibility.

At least one carrier is preferably relatively thin. This makes the carrier flexible and easy to handle. Preferably, at least one carrier has a thickness which is smaller than the thickness of at least one stage. It is also imaginable that at least part of at least one carrier is impermeable for air. For example at least part of the carrier which surrounds the part configured for carrying at least one substrate which is to be imprinted. At least one carrier can for example comprise at least one metal and/or at least one polymer. At least one carrier can for example comprise a metal foil, for example an aluminium foil. Further non-limiting examples which could be comprises by the carrier are textiles, fiber reinforced materials and/or woven or non-woven material.

Alternatively, at least part of the carrier can be substantially rigid. It is for example imaginable that the carrier provides support for the substrate during imprinting. The at least one carrier may also have a thickness which is larger than the thickness of at least one stage. For such embodiment, it is conceivable that at least one stage is substantially flexible.

At least one stage is preferably substantially uniform in terms of flatness, surface roughness and/or local stiffness. At least one stage can for example comprise at least one mineral and/or ceramic material. Further non-limiting examples whereof at least one stage can be comprises are granite, metal alloys, preferably aluminium or stainless steel. It is also imaginable that at least part of the stage comprises a conducive material. The width and/or length of at least one stage is preferably at least equal and preferably larger than the width and/or length of the substrate which is to be imprinted. The stage is preferably configured to substantially fully support the substrate. The width and/or length of at least one carrier is preferably at least equal to the width and/or length of at least one substrate which is to be imprinted. It is also imaginable that the width and/or length of at least one stage is at least equal and preferably larger than the width and/or length of the carrier. Preferably, the width and/or length of at least one carrier is at least equal and preferably larger than the width and/or length of the substrate which is to be imprinted.

In a preferred embodiment, at least one stage comprises at least one air channel. At least one air channel is in particular configured for the provision and/or intake of air. It is also conceivable that at least one stage comprises multiple air channels. The use of at least one air channel can provide for near frictionless movement of the carrier with respect to the stage in particular via (compressed) air provided in the air channel(s). Hence, it is conceivable that the mutual displacement wherein at least one carrier and at least one stage are mutually displaced from the adjusting configuration to imprinting configuration is achieved via air provided in at least one air channel. Adjusting of the carrier with respect to the stage can also be facilitated and/or supported via air provided in at least one air channel. It is for example conceivable that a vacuum, partial vacuum or sub atmospheric pressure is applied to the air channel(s) such that the carrier, for example a carrier comprising a belt, will be (temporarily) fixated to the stage. Instead of or in addition to air also any further medium can be applied in air channel(s).

The system according to the invention may comprise at least one air pressure regulator configured for providing an air flow between at least one stage and at least one carrier. At least one air pressure regulator could for example be configured for providing an overpressure, an negative pressure, a partial vacuum and/or a vacuum between at least one stage and at least one carrier. At least one air pressure regulator could also provide a flow of air in at least one air channel of the stage, if applied. By increasing pressure between the carrier and the stage, they can hoover with very little mutual friction. This is desirable when adjusting the mutual position of the carrier and the stage, and thus when aligning the substrate. When the desired position of the substrate is attained, the air pressure can be decreased, preferably below 1 atmosphere, to increase friction, and to make sure the carrier and the stage, and also the substrate provided upon the carrier are substantially fixated during imprinting. Additional to the friction between the carrier and the stage, it is desirable to also be able to decrease air pressure between the carrier and the substrate. In that way, unwanted displacement of the substrate laying on the carrier layer can be avoided. A conventional solution is to only rely on gravity. In order to be able to create a low air pressure between the carrier and the substrate, at the same time and using the same tools used for decreasing air pressure between the carrier and the stage, it is beneficial if air is able to move through the carrier.

In an optional embodiment, it is conceivable that the system comprises a heater for heating and/or cooling at least part of the roller, in particular for heating and/or cooling at least part of the flexible stamp. Heating and/or cooling at least part of the roller could further optimize the imprinting process.

In a preferred embodiment, the system comprises at least two rollers configured for rolling at least one substantially flexible stamp over at least one substrate which is to be imprinted. The system may for example comprise a plurality of rollers according to the present invention. It is also imaginable that at least one roller is a delaminating roller and/or a separation roller, in particular for separating and/or delaminating at least one flexible stamp from the substrate.

The system may comprise at least one housing, wherein at least one least one roller and at least one stage are received within and/or attached to said housing. Such housing could also be referred to as a frame. The use of a housing can positively contribute to the ease of alignment of at least one stage with respect to at least one roller. It is for example imaginable that the housing restricts mutual displacement between the roller and the stage in a direction differing from the imprint direction. It is for example imaginable that the housing enables mutual displacement between the roller and the stage in the imprint direction, or x-direction and the vertical direction, Rz direction, but that mutual displacement in the y-direction is limited.

The system could optionally comprise at least one substantially flexible stamp configured for imprinting, in particular nanoimprinting. The substantially flexible stamp preferably comprises at least one textured area. The substantially flexible stamp is in particular positioned within the system such that at least one carrier, and in particular at least one substrate provided thereon, and the textured area of the substantially flexible stamp are substantially aligned, at least in the imprinting configuration. At least one substantially flexible stamp is preferably substantially transparent and/or translucent. This is for example beneficial for the ease of curing and/or hardening of a resin applied in the imprinting process. The system may optionally comprise at least one applicator for applying at least one resin, preferably a UV curable resin, onto at least one substrate and/or at least one flexible stamp.

The system could possibly comprise at least one visual inspection device, for example but not limited to at least one camera. At least one visual inspection device can for example be configured to determine the location of at least one substrate which is to be imprinted. It is also conceivable that at least one visual inspection device is configured to determine the location of at least one carrier and/or at least one stage. At least one control unit could be configured to control the mutual displacement between at least one carrier and at least one stage, and/or the mutual displacement between at least one stage and at least one roller, based upon the data obtained via the visual inspection means.

At least one substrate which is to be imprinted is for example a glass substrate, silicon wafer, metal substrate, a polymer substrate or a combination thereof. At least one substrate is in particular a plate like substrate. The substrate can optionally have a relief pattern. The system according to the present invention may comprise at least one supply unit for supplying at least one substrate upon at least one carrier. In this way, the process can be further optimized. At least one supply unit is for example configured to slide at least one substrate onto at least one carrier. At least one supply unit may for example comprise at least one pusher element. Optionally the system could further comprise at least one curing device, for example at least one UV curing device. The curing device can be configured for curing the imprinted substrate during and/or after the imprinting.

In yet a further possible embodiment, it is imaginable that the system, and in particular at least one carrier and/or at least stage comprises at least one removable mock substrate. At least one mock substrate is preferably configured to be positioned adjacent to the substrate which is to be imprinted in particular in order to locally equalize with the height of the substrate which is to be imprinted. This will further optimize the imprinting process, in particular such that formation of irregularities at the edges of the substrate can be prevented. The roller can provide a more equalized pressure over the substrate. At least one mock substrate can be made of the same material as the substrate which is to be imprinted. At least one mock substrate preferably has a thickness substantially equal to the thickness of the substrate which is to be imprinted. At least one mock substrate could also be referred to as or dummy substrate or as compensating substrate aid. It is also conceivable that the system comprises multiple removable mock substrates. At least one mock substrate can be positioned upon and/or underneath at least one carrier.

The invention also relates to a process for imprinting, in particular nanoimprinting, comprising the steps of:
providing at least one system according to the present invention;
providing at least one substrate which is to be imprinted upon at least one carrier;
bringing at least one carrier and at least one stage into an adjusting configuration;
aligning the mutual position of at least one carrier and at least one stage such that the substrate is substantially aligned at least with respect to at least one stage and/or at least stamp; and
bringing at least one carrier and at least one stage into an imprinting configuration, wherein at least one carrier engages at least one stage and/or is positioned upon at least one stage such that the substrate provided upon at least one carrier can be imprinted.

The process according to the present invention has similar benefits as described for the system according to the present invention. The imprinting process according to the present invention is more efficient in terms of aligning and less prone to damaging of the substrate.

It is for example conceivable that the alignment step is applied such that the substrate is substantially aligned with at least one roller and/or with at least one substantially flexible stamp. This may positively contribute to the overall imprinting process and imprinting quality and repeatability. The process may further comprise the step of imprinting of the substrate via rolling at least one substantially flexible stamp over the substrate. The process may further comprise the step of increasing the pressure between the carrier and the stage during the aligning step and/or decreasing the pressure between the carrier and the stage during the imprinting step. It is for example also imaginable that fixation of at least one substrate on the carrier is achieved via a (partial) vacuum and/or that the carrier is displaced towards the stage via a (partial) vacuum. The process may also comprise the step of removal of the imprinted substrate from the system. The invention also relates to a process for imprinting, in particular nanoimprinting, in particular by making use of a system according to the present invention, wherein alignment of at least one substrate which is to be imprinted is done via adjusting the position of at least one carrier upon which a substrate which is to be imprinted is positioned.

The invention will be further elucidates by means of the following non-limitative clauses.

1. System for imprinting, in particular nanoimprinting, comprising:
at least one roller configured for exerting pressure onto at least one flexible stamp and/or at least one substrate which is to be imprinted;
at least one carrier configured for carrying at least one substrate which is to be imprinted; and
at least one stage configured for providing support to at least one carrier and/or at least one substrate during imprinting;
   wherein at least one roller and at least one stage are mutually displaceable in an imprint direction in particular such that imprinting is facilitated; and
   wherein at least one carrier and at least one stage are mutually displaceable between at least:
an adjusting configuration, wherein said carrier and said stage are mutually displaceable in at least one direction which differs from the imprint direction such that at least one substrate provided upon said carrier can be aligned with respect to said stage; and
an imprinting configuration, wherein at least one carrier engages at least one stage such that at least one substrate provided upon said carrier can be imprinted.

2. System according to clause 1, wherein the mutual distance between at least one roller and at least one stage is adjustable.

3. System according to any of the previous clauses, wherein, at least in the adjusting configuration, said carrier and said stage are mutually displaceable in multiple directions within a plane which is substantially parallel to a plane defined by said stage and/or said carrier, wherein at least one direction differs from the imprint direction.

4. System according to any of the previous clauses, wherein the mutual distance between at least one roller and at least one carrier is adjustable and/or wherein the mutual distance between at least one carrier and at least one stage is adjustable.

5. System according to any of the previous clauses, comprising at least one primary actuator for adjusting the mutual position of at least one roller and at least one stage.

6. System according to any of the previous clauses, comprising at least one secondary actuator for adjusting the position of at least one carrier with respect to at least one stage.

7. System according to any of the previous clauses, wherein at least part of at least one carrier is substantially situated between at least one roller and at least one stage at least in the imprinting configuration.

8. System according to any of the previous clauses, wherein at least part of at least one carrier substantially encloses at least part of at least one stage.

9. System according to any of the previous clauses, wherein at least one carrier comprises at least one belt, in particular an endless belt.

10. System according to clause 9, wherein at least one endless belt encloses at least one stage such that the belt direction of the endless belt is substantially equal to or opposite of the imprint direction.

11. System according to any of the previous clauses, wherein at least part of at least one carrier is permeable to air.

12. System according to any of the previous claims, wherein at least part of at least one carrier comprises a porous structure.

13. System according to any of the previous clauses, wherein at least part of at least one carrier comprises a mesh, a raster, a matrix, a perforated structure and/or a woven structure.

14. System according to any of the previous clauses, wherein at least part of at least one carrier is impermeable for air.

15. System according to any of the previous clauses, comprising at least one air pressure regulator configured for providing an air flow between at least one stage and at least one carrier.

16. System according to any of the previous clauses, wherein at least one stage comprises at least one air channel for the provision and/or intake of air.

17. System according to any of the previous clauses, comprising at least one heater for heating and/or cooling of at least part of the roller.

18. System according to any of the previous clauses, comprising at least two rollers configured for rolling at least one substantially flexible stamp over at least one substrate which is to be imprinted.

19. System according to any of the previous clauses, comprising at least one housing, wherein at least one least one roller and at least one stage are received within and/or attached to said housing.

20. System according to any of the previous clauses, comprising at least one substantially flexible stamp configured for imprinting, in particular nanoimprinting.

21. System according to clause 20, wherein at least one substantially flexible stamp comprises at least one textured area.

22. System according to any of the previous clauses, comprising at least one visual inspection device.

23. System according to any of the previous clauses, comprises at least one supply unit for supplying at least one substrate upon at least one carrier.

24. Process for imprinting, in particular nanoimprinting, comprising the steps of:
providing at least one system according to any of the previous clauses;
providing at least one substrate which is to be imprinted upon at least one carrier;
bringing at least one carrier and at least one stage into an adjusting configuration;
aligning the mutual position of at least one carrier and at least one stage such that the substrate is substantially aligned at least with respect to at least one stage and/or at least one flexible stamp; and
bringing at least one carrier and at least one stage into an imprinting configuration, wherein at least one carrier engages at least one stage such that the substrate provided upon at least one carrier can be imprinted.

25. Process according to clause 24, further comprising the step of imprinting of the substrate via rolling at least one substantially flexible stamp over the substrate.

26. Process according to clause 24 or 25, wherein the pressure between the carrier and the stage is increased during the aligning step and/or wherein the pressure between the carrier and the stage is decreased the imprinting step.

### BRIEF DESCRIPTION OF THE DRAWINGS

The terms Fig., Figs., Figure, and Figures are used interchangeably in the specification to refer to the corresponding figures in the drawings.

The invention will be further elucidated by means of non-limiting exemplary embodiments illustrated in the following figures, in which:

FIGS. 1a and 1b show a schematic representation of an example of a system according to the present invention;

FIGS. 2a, 2b and 2c show a second possible embodiment of a system according to the present invention;

FIGS. 3a and 3b show a third possible embodiment of a system according to the present invention; and

FIGS. 4a and 4b show a fourth possible embodiment of a system according to the present invention.

Within these figures, similar reference numbers correspond to similar or equivalent elements or features.

### DESCRIPTION OF THE INVENTION

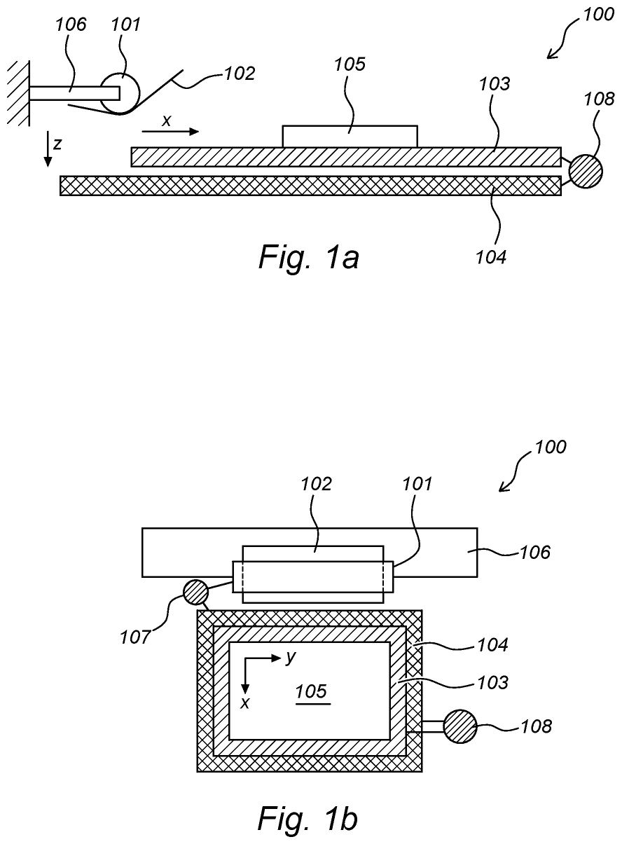

FIGS. 1a and 1b show a schematic representation of a system 100 according to the present invention. FIG. 1a shows a cross sectional side view of the system 100 and FIG. 1b shows a top view. The system 100 is configured for imprinting, in particular nanoimprinting. The system 100 comprises thereto a roller 101 configured for rolling at least one flexible stamp 102 over a substrate 105 which is to be imprinted, a carrier 103 carrying the substrate 105 and a stage 104. The stage 104 is configured for providing support to the carrier 104 and the substrate 105 during imprinting. In the shown embodiment, the system 100 comprises a housing 106, and the roller 101 is attached to said housing 106 and the stage 104 is movably attached to said housing 106. The roller 101 and/or the stage 104 are displaceable in an imprint direction, in or inverse to the shown configuration the x-direction. The carrier 103 and the stage 104 are mutually displaceable between at least an adjusting configuration, wherein the carrier 103 and the stage 104 are preferably positioned at a distance from each other and wherein said carrier and said stage are mutually displaceable in at least one direction which differs from the imprint direction such that the substrate 105 provided upon the carrier 103 can be aligned with respect to the stage 104 and/or with respect to the flexible stamp 102 and an imprinting configuration, wherein the carrier 103 engages the stage 104 and is in particular positioned directly upon the stage 104 such that the substrate 105 provided upon the carrier 103 can be imprinted. FIG. 1a shows the system in an adjusting configuration, since the carrier 103 and stage 104 are positioned at a distance from each other in the z-direction. The system 100 further comprises a primary actuator 107 for adjusting the mutual position of the roller 101 and at least one stage 104. The system 100 also comprises a secondary actuator 108 for adjusting the position of the carrier 103 with respect to the stage 104.

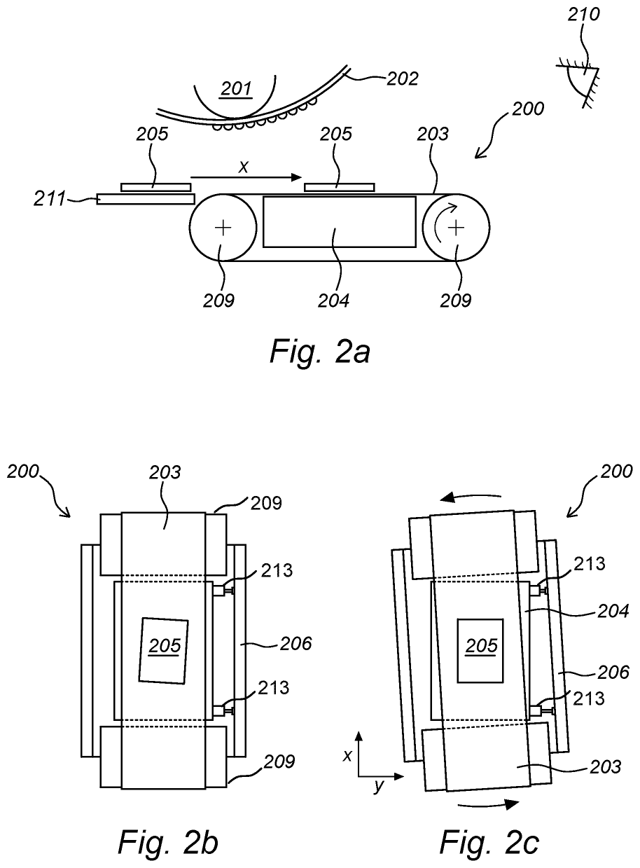

FIGS. 2a, 2b and 2c show a second possible embodiment of a system 200 according to the present invention. FIG. 2a shows a schematic representation in side view of the system 200, where FIGS. 2b and 2c show a top view of part of the system 200. The system 200 comprises a roller 201 configured for rolling at least one substantially flexible stamp 202 over a substrate 205 which is to be imprinted. The flexible stamp 202 can also be wrapped around the roller. Or the flexible stamp can be an integrated part of the roller (i.e. being an textured roller). The substantially flexible stamp 202 comprises a textured area. The system 200 further comprises a carrier 203 and a stage 204. In the shown embodiment, the system 200 comprises a housing 206. In the shown embodiment, the carrier 203 comprises an endless belt 203. The endless belt 203 co-acts with two guidance rollers 209. The endless belt 203 is basically attached around the guidance rollers 209 which are positioned at a distance from each other. In the shown embodiment, part of the housing 206 is attached to the guidance rollers 209 of the carrier 203 and to the stage 204. The housing 206 is in particular connected to at least two guidance rollers 209 of the at least one endless belt 203 via at least two actuators 213, in particular voice coil actuators 213. The guidance rollers 209 may also be driven rollers for driving endless belt 203. FIGS. 2b and 2c show that the alignment of the substrate 205 with respect to the stage 204 can be done by adjusting the position of the carrier 203, in particular the endless belt 203, with respect to the stage 204. It can be seen that the configuration enables mutual displacement of the carrier 203 with respect to the stage 204 in a direction (y-direction) different from the imprint direction (x-direction). FIG. 2b shows an initial configuration, wherein FIG. 2c shows an accurate alignment of the substrate 205 with respect to the stage 204 and/or with respect to a flexible stamp. The system 200 is in particular configured such that the carrier 203 can be make a tilting and/or partially rotating movement with respect to the stage 204. The carrier 203 thereby substantially encloses the stage 204. Part of the carrier 203 is substantially situated between the roller 201 and the stage 204. The system 200 could further optionally comprise at least one visual inspection device 210 and/or at least one supply unit 211 for supplying at least one substrate 205 upon at least one carrier 203.

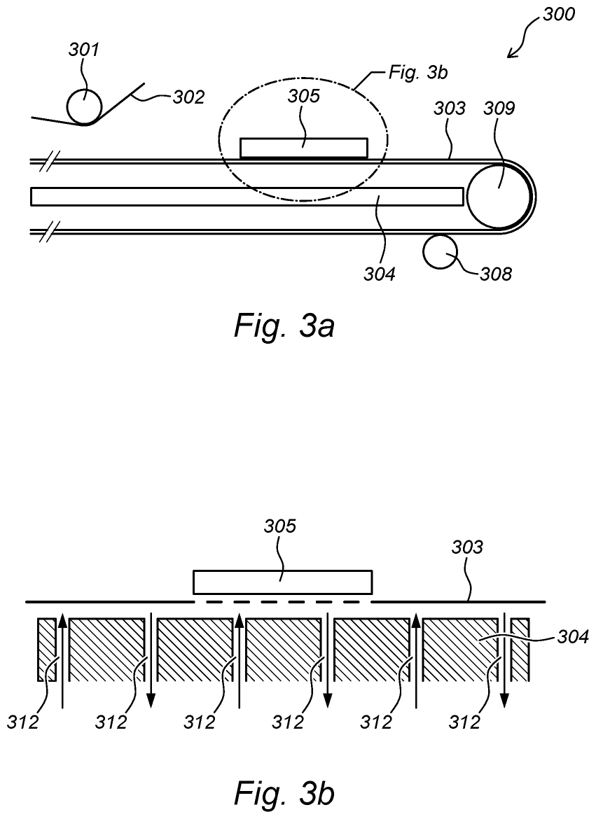

FIGS. 3a and 3b show a third possible embodiment of a system 300 according to the present invention. FIG. 3a shows a schematic representation in side view of the system 300, and FIG. 3b shows a detailed view of part thereof. The system 300 comprises a roller 301 configured for rolling at least one substantially flexible stamp 302 over a substrate 305 which is to be imprinted. The system 300 further comprises a carrier 303 and a stage 304. The carrier 303 comprises an endless belt 303 which is received over a guidance roller 309. The system 300 also comprises a secondary actuator 308 for adjusting the position of the carrier 303 with respect to the stage 304. Part of the carrier 303 is permeable to air. Thereto at least part of the carrier 303 comprises a porous structure. FIG. 3b shows that part of the carrier 303 below the substrate 305 comprises openings through which air can pass. A further part of the carrier 303 is impermeable to air. The stage 304 comprises air channels 312 for the provision and/or intake of air. This can for example be compressed air and/or (partial) vacuum. The system 300 enables in particular that an increased pressure can applied between the carrier 303 and the stage 304 during the aligning step and/or that a decreased pressure can be applied between the carrier 303 and the stage 304 during the imprinting step.

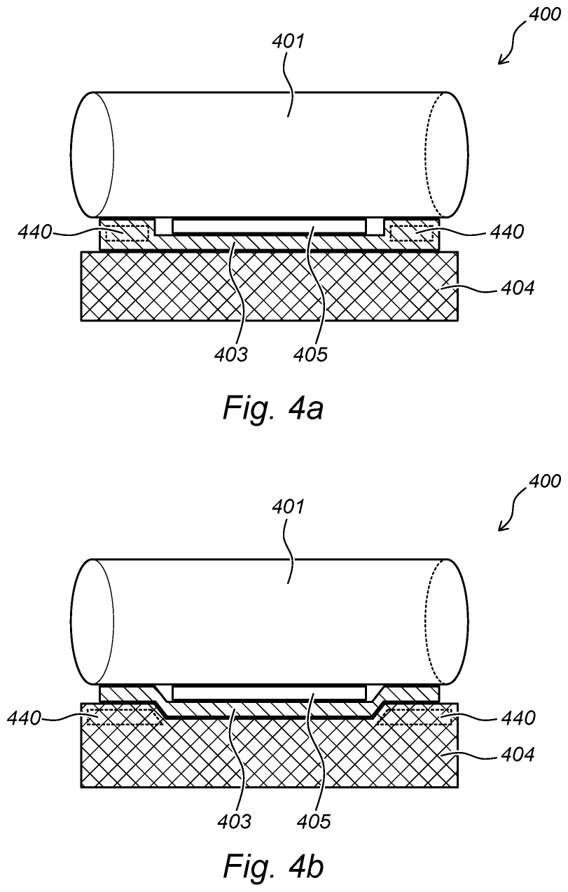

FIGS. 4a and 4b show two embodiments of a fourth possible embodiment of a system 400 according to the present invention wherein the system 400 comprises removable mock substrates 440. FIG. 4a shown an embodiment wherein the carrier 403 comprises removable mock substrates 440. FIG. 4b shows an embodiment wherein the stage 404 comprises removable mock substrates 440. The mock substrates 440 are positioned adjacent to the substrate 405 which is to be imprinted. It can be seen that the mock substrates 440 result in that the height of the top surface of the carrier 403 is in line with the height of the top surface of the substrate 405 which is to be imprinted locally at the parts where the mock substrates 440 are present. In this case, the roller 401 can apply a more even pressure onto the substrate 405 which is to be imprinted.

It will be clear that the invention is not limited to the exemplary embodiments which are illustrated and described here, but that countless variants are possible within the framework of the attached claims, which will be obvious to the person skilled in the art. In this case, it is conceivable for different inventive concepts and/or technical measures of the above-described variant embodiments to be completely or partly combined without departing from the inventive idea described in the attached claims.

The verb ‘comprise’ and its conjugations as used in this patent document are understood to mean not only ‘comprise’, but to also include the expressions ‘contain’, ‘substantially contain’, ‘formed by’ and conjugations thereof.

1. A system for imprinting, in particular nanoimprinting, comprising:
at least one roller configured for exerting pressure onto at least one flexible stamp and/or at least one substrate which is to be imprinted;
at least one carrier configured for carrying at least one substrate which is to be imprinted; and
at least one stage configured for providing support to at least one carrier and/or at least one substrate during imprinting;
wherein at least one roller and at least one stage are mutually displaceable in an imprint direction in particular such that imprinting is facilitated; and
wherein at least one carrier and at least one stage are mutually displaceable between at least:
an adjusting configuration, wherein said carrier and said stage are mutually displaceable in at least one direction which differs from the imprint direction such that at least one substrate provided upon said carrier can be aligned with respect to said stage; and
an imprinting configuration, wherein at least one carrier engages at least one stage such that at least one substrate provided upon said carrier can be imprinted;
wherein the at least one carrier comprises at least one endless belt, wherein at least part of the endless belt encloses at least part of the at least one stage, at least in the imprinting configuration.

2. The system according to claim 1, wherein the mutual distance between at least one roller and at least one stage is adjustable.

3. The system according to claim 1, wherein, at least in the adjusting configuration, said carrier and said stage are mutually displaceable in multiple directions within a plane which is substantially parallel to a plane defined by said stage and/or said carrier, wherein at least one direction differs from the imprint direction.

4. The system according to claim 1, wherein the mutual distance between at least one roller and at least one carrier is adjustable and/or wherein the mutual distance between at least one carrier and at least one stage is adjustable.

5. The system according to claim 1, comprising at least one primary actuator for adjusting the mutual position of at least one roller and at least one stage.

6. Thesystem according to claim 1, comprising at least one secondary actuator for adjusting the position of at least one carrier with respect to at least one stage.

7. The system according to claim 1, wherein at least part of at least one carrier is substantially situated between at least one roller and at least one stage at least in the imprinting configuration.

8. The system according to claim 1, wherein at least part of at least one carrier substantially encloses at least part of at least one stage.

9. The system according to claim 1, wherein the at least one endless belt is basically attached around at least two guidance rollers which are positioned at a distance from each other.

10. The system according to claim 1, wherein at least one endless belt encloses at least one stage such that the belt direction of the endless belt is substantially equal to or opposite of the imprint direction.

11. The system according to claim 1, wherein at least part of at least one carrier is permeable to air.

12. The system according to claim 1, wherein at least part of at least one carrier comprises a porous structure.

13. The system according to claim 1, wherein at least part of at least one carrier comprises a mesh, a raster, a matrix, a perforated structure and/or a woven structure.

14. The system according to claim 1, wherein at least part of at least one carrier is impermeable for air.

15. The system according to claim 1, comprising at least one air pressure regulator configured for providing an air flow between at least one stage and at least one carrier.

16. The system according to claim 1, wherein at least one stage comprises at least one air channel for the provision and/or intake of air.

17. The system according to claim 1, comprising at least one heater for heating and/or cooling of at least part of the roller.

18. The system according to claim 1, comprising at least two rollers configured for rolling at least one substantially flexible stamp over at least one substrate which is to be imprinted.

19. The system according to claim 1, comprising at least one housing, wherein at least one least one roller and at least one stage are received within and/or attached to said housing.

20. The system according to claim 1, comprising at least one substantially flexible stamp configured for imprinting, in particular nanoimprinting.

21. The system according to claim 20, wherein at least one substantially flexible stamp comprises at least one textured area.

22. The system according to claim 1, comprising at least one visual inspection device.

23. The system according to claim 1, comprises at least one supply unit for supplying at least one substrate upon at least one carrier.

24. A process for imprinting, in particular nanoimprinting, comprising the steps of:
providing at least one system according to claim 1;
providing at least one substrate which is to be imprinted upon at least one carrier;
bringing at least one carrier and at least one stage into an adjusting configuration;
aligning the mutual position of at least one carrier and at least one stage such that the substrate is substantially aligned at least with respect to at least one stage and/or at least one flexible stamp; and
bringing at least one carrier and at least one stage into an imprinting configuration, wherein at least one carrier engages at least one stage such that the substrate provided upon at least one carrier can be imprinted.

25. The process according to claim 24, further comprising the step of imprinting of the substrate via rolling at least one substantially flexible stamp over the substrate.

26. The process according to claim 24, wherein the pressure between the carrier and the stage is increased during the aligning step and/or wherein the pressure between the carrier and the stage is decreased the imprinting step.
